(19) United States
(12) Patent Application Publication
(10) Pub. No.: US 2026/0254179 A1
(43) Pub. Date: Aug. 27, 2026

(54) BUSBAR MODULE

(71) Applicant: BIZLINK INTERNATIONAL CORP., New Taipei City (TW)

(72) Inventors: Chao WANG, New Taipei City (TW); Zengshi LAO, New Taipei City (TW); Haoran ZOU, New Taipei City (TW)

(21) Appl. No.: 19/539,014

(22) Filed: Feb. 13, 2026

(30) Foreign Application Priority Data
Feb. 21, 2025 (CN) 202520292549.6

(51) Int. Cl. H01R 25/16; H01M 50/209; H01M 50/507; H01M 50/522

(52) U.S. Cl. CPC H01R 25/162; H01M 50/209; H01M 50/507; H01M 50/522

(57) ABSTRACT

A busbar module for supplying power to a server includes: a housing, first and second busbars, an insulating member, and at least one pair of handles. The housing defines a length direction and includes a base plate and two side plates. The handles are disposed on outer surfaces of the side plates. Each handle is positioned away from the base plate such that a vertical distance between a geometric center of the handle and the base plate is at least one-half of the side plate width. This specific arrangement ensures the center of gravity is located below the handles during transport, facilitating stable handling of heavy modules ranging from 50 kg to 100 kg and minimizing safety hazards.

This application claims priority to China Application Serial Number 202520292549.6, filed February 21, 2025, which is herein incorporated by reference in its entirety.

### BACKGROUND

### Field of Invention

The present invention relates generally to the field of power distribution systems, and more particularly to a busbar module utilized for server racks in data centers.

### Description of Related Art

A busbar module is a power distribution system specifically designed for data center server racks, often compliant with Open Compute Project (OCP) specifications. The primary function of a busbar module is to efficiently and safely transmit power from a power shelf or a Power Supply Unit (PSU) to individual server nodes within a server rack through internal conductive bars, such as copper bars.

With the escalating demands for power transmission in modern data centers, the physical dimensions and weight of busbar modules have increased accordingly. In practical applications, the length of a busbar module may reach up to approximately 2 meters. Consequently, the overall weight of the module typically ranges between 50 kilograms and 100 kilograms.

However, due to these extreme dimensions and significant weight, conventional busbar modules are highly inconvenient to transport, move, or install into racks. Such difficulty in handling not only leads to excessive labor requirements but also poses substantial safety risks during operation. For instance, an unstable center of gravity or the lack of adequate gripping points can lead to accidental slipping or collisions, resulting in potential injuries or equipment damage. Therefore, there is an urgent need in the industry for a busbar module with an improved structure that facilitates ease of handling, improves labor efficiency, and minimizes safety hazards.

### SUMMARY

To achieve the above objectives, the present invention provides a busbar module for supplying power to a server.

According to an embodiment of the present invention, the busbar module includes a housing defining a length direction, where the housing includes a base plate and two side plates connected to two opposite sides of the base plate and extending along the length direction. Each of the side plates defines a side plate width perpendicular to the length direction. The module further includes a first busbar and a second busbar disposed within the housing and extending along the length direction, and an insulating member sandwiched between the first busbar and the second busbar and extending along the length direction. At least one pair of handles are respectively disposed on outer surfaces of the side plates.

In one embodiment, each of the handles is disposed at a position on the side plate away from the base plate. A vertical distance between a geometric center of each of the handles and the base plate is greater than or equal to one-half of the side plate width. Further, the vertical distance between the geometric center of each of the handles and the base plate may be greater than or equal to two-thirds of the side plate width.

In one embodiment, the number of handles may be at least four and is an even number, with at least four of the handles symmetrically disposed on the outer surfaces of the two side plates. The handles disposed on the same side plate are spaced apart from each other along the length direction.

In one embodiment, each of the handles includes a base and a grip. The grip and the base cooperatively define an opening for a hand to penetrate, and an opening direction of the opening is parallel to a direction of the side plate width. An inner surface of the grip facing the opening may be provided with an anti-slip texture or an anti-slip coating.

In one embodiment, each of the handles is integrally formed with the surface of the side plate, and a connection between each of the handles and the side plate is a continuous surface. The material of the handles is metal or hard plastic. An edge of each of the handles may comprise a fillet or a chamfer.

In one embodiment, each of the handles may be fixed to the side plate through at least one fastener that penetrates through the side plate, the first busbar, the second busbar, and the insulating member. An insulating sleeve may be disposed around a periphery of the fastener, passing through the first busbar and the second busbar. Additionally, each of the side plates may be provided with a mounting groove at a position where the handle is disposed, maintaining a predetermined insulation distance between the mounting groove and the first and second busbars.

In one embodiment, the insulating member may have a dimension in a direction of the side plate width that is larger than the dimensions of the first busbar and the second busbar, such that edges of the insulating member protrude beyond the first busbar and the second busbar. Furthermore, a thickness or a contour of each of the handles may be configured as a guide rail engagement member, and the position of each of the handles on the side plate may be asymmetrically disposed relative to a geometric center line of the side plate.

In one embodiment, a length of the housing along the length direction is 89 cm to 223 cm. A base plate width of the base plate is 32 mm to 39 mm, and a total weight of the busbar module is 50 kg to 100 kg.

According to another embodiment, to facilitate ergonomic lifting of heavy loads, each of the handles comprises a base and a grip that cooperatively define an opening for a hand to penetrate, wherein an opening direction of the opening is parallel to a direction of the side plate width.

In one embodiment, the vertical distance between a geometric center of each of the handles and the base plate is specifically configured to be greater than or equal to one-half of the side plate width. This arrangement ensures that when the busbar module is carried via the handles, an overall center of gravity of the busbar module is located below the handles, thereby maintaining vertical stability of the housing in the length direction.

In one embodiment, the busbar module is specifically dimensioned with a housing length of 89 cm to 223 cm and a base plate width of 32 mm to 39 mm, accommodating a total weight of 50 kg to 100 kg.

In summary, the busbar module of the present invention addresses the technical challenges associated with transporting heavy and elongated power distribution equipment. By strategically positioning the handles to lower the center of gravity, employing a reinforced fastening structure that penetrates through internal components, and integrating electrical safety features such as insulation distances and creepage paths, the present invention significantly improves handling stability, ensures structural integrity under heavy loads, and minimizes safety hazards for operators during installation and maintenance.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic structural perspective view of a busbar module according to an embodiment of the present invention;

FIG. 2 is a top view of the busbar module shown in FIG. 1;

FIG. 3 is a cross-sectional view taken along line A-A of FIG. 2, illustrating the internal arrangement of the busbars and the insulating member;

FIG. 4 is an enlarged perspective view of a handle of the busbar module, illustrating the structural details of a base and a grip; and

FIG. 5 is an enlarged partial cross-sectional view taken along line A-A of FIG. 2, specifically illustrating the fastening and mounting structure of the handle.

### DETAILED DESCRIPTION

The technical solutions in the embodiments of the present invention will be described clearly and completely below with reference to the accompanying drawings in the embodiments of the present invention. It is apparent that the described embodiments are only a portion of the embodiments of the present invention, rather than all of the embodiments. Based on the embodiments in the present invention, all other embodiments obtained by those of ordinary skill in the art without creative effort shall fall within the scope of protection of the present invention.

It should be noted that if directional indicators (such as up, down, left, right, front, back, etc.) are involved in the embodiments of the present invention, the directional indicators are only used to explain the relative positional relationship, movement, etc., between various components in a specific posture. If the specific posture changes, the directional indicators will change accordingly.

In addition, if descriptions involving "first," "second," etc., are involved in the embodiments of the present invention, the descriptions of "first," "second," etc., are for descriptive purposes only and should not be understood as indicating or implying their relative importance or implicitly indicating the number of indicated technical features. Thus, a feature defined by "first" or "second" may explicitly or implicitly include at least one such feature. Furthermore, if "and/or" appears in the text, its meaning includes three parallel solutions; taking "A and/or B" as an example, it includes solution A, solution B, or a solution where both A and B are satisfied simultaneously. In addition, the technical solutions between various embodiments can be combined with each other, provided that such combinations are based on what can be realized by those of ordinary skill in the art. When a combination of technical solutions is contradictory or impossible to achieve, such a combination should be considered non-existent and is not within the scope of protection claimed by the present invention. If the present invention mentions "A includes/comprises B," unless explicitly excluded or not allowed by the context, the inclusion or comprehension therein means that A includes one or more B.

It should be noted that the drawings of the present invention are drawn to scale, and the dimensional proportions and relative positions of various components should be considered as part of the disclosure.

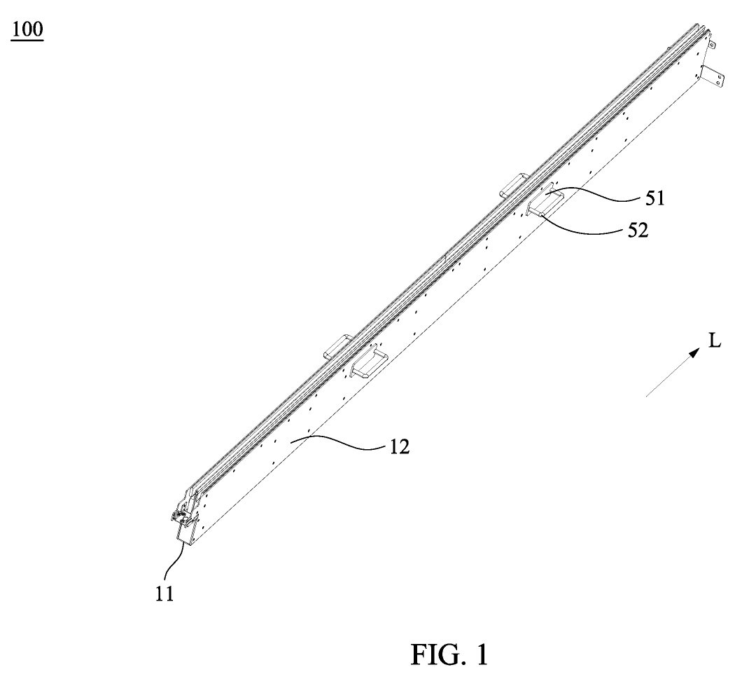

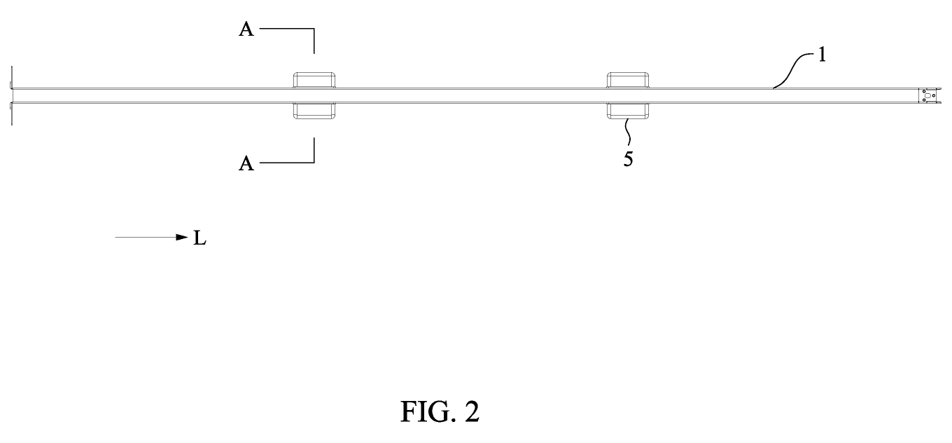

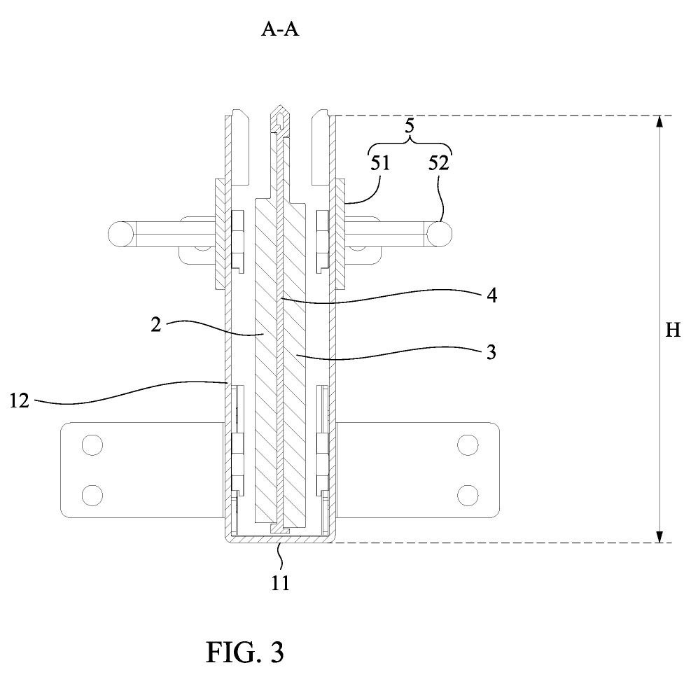

Please refer to FIGS. 1 to FIG. 3 together. FIG. 1 is a schematic structural perspective view of a busbar module 100 according to an embodiment of the present invention; FIG. 2 is a top view thereof; and FIG. 3 is a cross-sectional view taken along line A-A of FIG. 2. As illustrated, the busbar module 100 is configured to supply power to a server. The busbar module 100 comprises a housing 1, a first busbar 2, a second busbar 3, an insulating member 4, and at least one pair of handles 5.

The housing 1 defines a length direction L and serves as the main structural body. Specifically, the housing 1 comprises a base plate 11 and two side plates 12. The two side plates 12 are connected to two opposite sides of the base plate 11 and extend along the length direction L. As best seen in the cross-sectional view of FIG. 3, the housing 1 may define a substantially U-shaped cross-section. Each of the side plates 12 defines a side plate width (which corresponds to the vertical height H of the side plate in FIG. 3) perpendicular to the length direction L.

The first busbar 2 and the second busbar 3 are accommodated within the housing 1 and extend along the length direction L to transmit electrical power. The insulating member 4 is sandwiched between the first busbar 2 and the second busbar 3 and extends along the length direction L to electrically isolate the two busbars. In an embodiment, as shown in FIG. 3, a dimension of the insulating member 4 in a direction of the side plate width is larger than dimensions of the first busbar 2 and the second busbar 3. Consequently, edges of the insulating member 4 protrude beyond the first busbar 2 and the second busbar 3. This protruding structure creates an extended creepage path between the conductive busbars and the handles 5 or the housing 1, thereby enhancing electrical safety during handling.

In an embodiment, referring to the dimensions illustrated in FIGS. 1 and FIG. 2, a length of the housing 1 along the length direction L is 89 cm to 223 cm, and a base plate width of the base plate 11 is 32 mm to 39 mm. The total weight of the busbar module 100 ranges from 50 kg to 100 kg. Due to this high aspect ratio and significant weight, the stability of the center of gravity during transport is critical.

In an embodiment, as illustrated in FIGS. 1 and FIG. 2, the arrangement of the handles 5 is specifically configured to accommodate the elongated structure of the housing 1. The number of the handles 5 is at least four and is an even number. Specifically, at least four of the handles 5 are symmetrically disposed on the outer surfaces of the two side plates 12. Furthermore, the handles 5 disposed on the same side plate 12 are spaced apart from each other along the length direction. This distributed arrangement allows multiple operators to lift the busbar module 100 simultaneously from both sides, thereby distributing the weight load (50 kg to 100 kg) and preventing the housing 1 from bending or deforming due to stress concentration during transport.

To ensure stability, as clearly shown in FIG. 3, each of the handles 5 is disposed at a specific position on the side plate 12. In an embodiment, each handle 5 is positioned away from the base plate 11, wherein a vertical distance between a geometric center of each handle 5 and the base plate 11 is greater than or equal to one-half (1/2) of the side plate width. In another embodiment, this vertical distance is greater than or equal to two-thirds (2/3) of the side plate width. By positioning the handles 5 at an upper portion of the side plates 12, when the busbar module 100 is lifted via the handles 5, a center of gravity of the entire busbar module 100 is naturally located below the handles 5. This pendulum-like effect maintains the vertical orientation of the housing 1 and prevents the module from flipping or tilting during transport.

Regarding the structure of the handles, as shown in FIGS. 1 and FIG. 3, each handle 5 comprises a base 51 and a grip 52. The base 51 and the grip 52 cooperatively define an opening for a hand to penetrate therethrough. In an embodiment, an opening direction of the opening is parallel to a direction of the side plate width (i.e., vertically oriented). This orientation allows operators to insert their hands from the bottom up, which is ergonomically more suitable for lifting heavy loads compared to horizontal handles. In an embodiment, the material of the handles 5 is metal or hard plastic. It should be noted that, in an alternative embodiment distinct from the assembly shown in the figures, the handle 5 is integrally formed with the surface of the side plate 12. In this configuration, a connection therebetween is a continuous surface, thereby ensuring structural integrity under heavy loads.

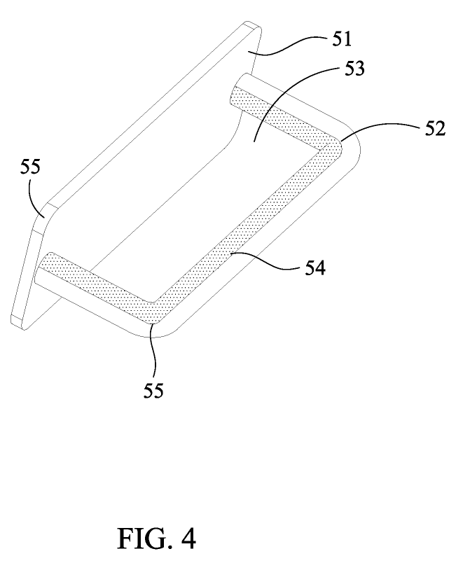

Please refer to FIG. 4, which illustrates specific surface details and functional configurations of the handle 5. As shown in this enlarged view, to enhance handling safety for the heavy busbar module 100, an inner surface of the grip 52 facing the opening 53 is provided with an anti-slip texture 54 (or an anti-slip coating). This feature increases friction to prevent the module from slipping out of an operator's hand, particularly when wearing industrial protective gloves. Additionally, edges of the handle 5, including those of the grip 52 and the base 51, are processed with a fillet 55 or a chamfer. This smooth edge design prevents the operator from being cut or injured by sharp edges during lifting operations.

In an embodiment, the handle 5 is further configured to serve a dual function. The thickness or outer contour of the base 51 or the grip 52 is shaped as a guide rail engagement member. When the busbar module 100 is installed into a server rack (not shown), the handle 5 is adapted to engage with a guide rail of the rack to facilitate alignment. Furthermore, although FIG. 1 illustrates a symmetric arrangement, in an alternative embodiment, the handle 5 may be asymmetrically disposed relative to a geometric center line of the side plate 12. This asymmetry acts as a foolproof mechanism, creating mechanical interference with the server rack if the busbar module 100 is inserted in an incorrect orientation, thereby preventing improper installation.

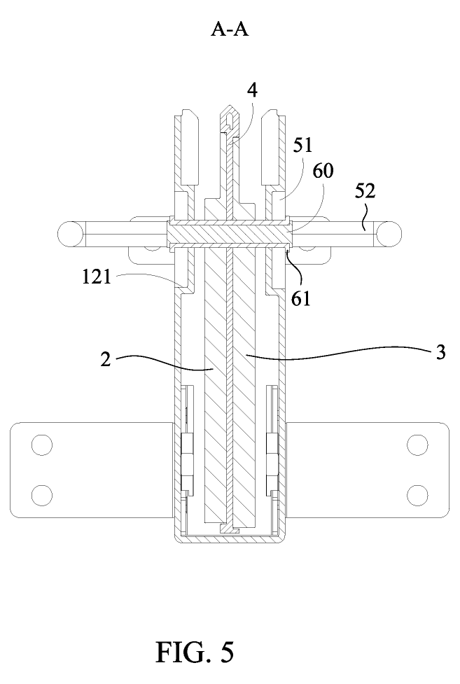

Please refer to FIG. 5, which is an enlarged partial cross-sectional view highlighting the fastening mechanism and electrical safety structure. In this embodiment, the side plate 12 forms a mounting groove 121 by recessing a portion of the side plate 12 toward the interior of the housing 1. The base 51 of the handle 5 is seated within the mounting groove 121. This recessed configuration positions the handle 5 while ensuring a predetermined insulation distance is maintained between the handle attachment point and the internal conductive components (first busbar 2 and second busbar 3).

Structurally, the handle 5 is integrated with the internal components to support the module's weight. At least one fastener 60 penetrates through the side plate 12 (at the mounting groove 121), the first busbar 2, the insulating member 4, and the second busbar 3. By penetrating these layers, the fastener 60 provides a clamping force that mechanically locks the handle 5, the housing 1, and the internal busbars 2, 3 together. To prevent electrical short circuits, an insulating sleeve 61 is disposed around a periphery of the fastener 60 and passes through the first busbar 2 and the second busbar 3, ensuring the conductive fastener 60 remains electrically insulated from the busbars.

In conclusion, the busbar module of the present invention provides a comprehensive solution for safe and efficient handling. Through the specific arrangement of the handles (symmetric, spaced apart, and positioned at an upper portion), the structural reinforcement (penetrating fasteners and mounting grooves), and the detailed safety designs (anti-slip grips, chamfered edges, and insulation sleeves), the present invention effectively solves the problems of instability, housing deformation, and electrical risks found in the prior art when moving heavy busbar modules. The resulting module is robust, ergonomically optimized, and safe for deployment in modern data centers.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A busbar module for supplying power to a server, comprising:
a housing defining a length direction, the housing comprising a base plate and two side plates connected to two opposite sides of the base plate and extending along the length direction, wherein each of the side plates defines a side plate width perpendicular to the length direction;
a first busbar and a second busbar disposed within the housing and extending along the length direction;
an insulating member sandwiched between the first busbar and the second busbar and extending along the length direction; and
at least one pair of handles respectively disposed on outer surfaces of the side plates.

2. The busbar module according to claim 1, wherein each of the handles is disposed at a position on the side plate away from the base plate, and a vertical distance between a geometric center of each of the handles and the base plate is greater than or equal to one-half of the side plate width.

3. The busbar module according to claim 2, wherein the vertical distance between the geometric center of each of the handles and the base plate is greater than or equal to two-thirds of the side plate width.

4. The busbar module according to claim 1, wherein a number of the handles is at least four and is an even number, and at least four of the handles are symmetrically disposed on the outer surfaces of the two side plates.

5. The busbar module according to claim 4, wherein the handles disposed on the same side plate are spaced apart from each other along the length direction.

6. The busbar module according to claim 1, wherein each of the handles comprises a base and a grip, the grip and the base cooperatively define an opening for a hand to penetrate therethrough, and an opening direction of the opening is parallel to a direction of the side plate width.

7. The busbar module according to claim 6, wherein an inner surface of the grip facing the opening is provided with an anti-slip texture or an anti-slip coating.

8. The busbar module according to claim 1, wherein each of the handles is integrally formed with the surface of the side plate, and a connection between each of the handles and the side plate is a continuous surface.

9. The busbar module according to claim 1, wherein a material of the handles is metal or hard plastic.

10. The busbar module according to claim 1, wherein an edge of each of the handles comprises a fillet or a chamfer.

11. The busbar module according to claim 1, wherein each of the handles is fixed to the side plate through at least one fastener, and the fastener penetrates through the side plate, the first busbar, the second busbar, and the insulating member.

12. The busbar module according to claim 11, wherein an insulating sleeve is disposed around a periphery of the fastener, and the insulating sleeve passes through the first busbar and the second busbar.

13. The busbar module according to claim 1, wherein each of the side plates is provided with a mounting groove at a position where the handle is disposed, and a predetermined insulation distance is maintained between the mounting groove and the first and second busbars.

14. The busbar module according to claim 1, wherein a dimension of the insulating member in a direction of the side plate width is larger than dimensions of the first busbar and the second busbar, and edges of the insulating member protrude beyond the first busbar and the second busbar.

15. The busbar module according to claim 1, wherein a thickness or a contour of each of the handles is configured as a guide rail engagement member.

16. The busbar module according to claim 15, wherein a position of each of the handles on the side plate is asymmetrically disposed relative to a geometric center line of the side plate.

17. The busbar module according to claim 1, wherein a length of the housing along the length direction is 89 cm to 223 cm, a base plate width of the base plate is 32 mm to 39 mm, and a total weight of the busbar module is 50 kg to 100 kg.

18. A busbar module for supplying power to a server, comprising:
a housing defining a length direction, the housing comprising a base plate and two side plates connected to two opposite sides of the base plate and extending along the length direction, wherein each of the side plates defines a side plate width perpendicular to the length direction;
a first busbar and a second busbar disposed within the housing and extending along the length direction;
an insulating member sandwiched between the first busbar and the second busbar and extending along the length direction; and
at least one pair of handles respectively disposed on outer surfaces of the side plates,
wherein each of the handles comprises a base and a grip, the grip and the base cooperatively define an opening for a hand to penetrate therethrough, and an opening direction of the opening is parallel to a direction of the side plate width.

19. The busbar module according to claim 18, wherein each of the handles is disposed at a position on the side plate away from the base plate, and a vertical distance between a geometric center of each of the handles and the base plate is greater than or equal to one-half of the side plate width, whereby when the busbar module is carried via the handles, an overall center of gravity of the busbar module is located below the handles to maintain vertical stability of the housing in the length direction.

20. The busbar module according to claim 19, wherein a length of the housing along the length direction is 89 cm to 223 cm, a base plate width of the base plate is 32 mm to 39 mm, and a total weight of the busbar module is 50 kg to 100 kg.
